(19) United States
(12) Patent Application Publication
(10) Pub. No.: US 2012/0138351 A1
(43) Pub. Date: Jun. 7, 2012

(54) CIRCUIT BOARD

(75) Inventor: I-HSIU LEE, Tu-Cheng (TW)

(73) Assignee: CHI MEI COMMUNICATION SYSTEMS, INC., Tu-Cheng (TW)

(21) Appl. No.: 13/078,090

(22) Filed: Apr. 1, 2011

(30) Foreign Application Priority Data
Dec. 7, 2010 (TW) 99223723

(51) Int. Cl. H05K 1/11

(52) U.S. Cl. 174/261

(57) ABSTRACT

The circuit board includes a base board and a pad array mounted on the base board. The pad array includes a plurality of spaced first pads, two second pads, and two third pads. The first pads, the second pads, and the third pads are all parallel to each other. The third pads are between the first pads and the second pads. The first pads electronically and physically connect to an electric element. The second pads and third pads physically connect to the electric element.

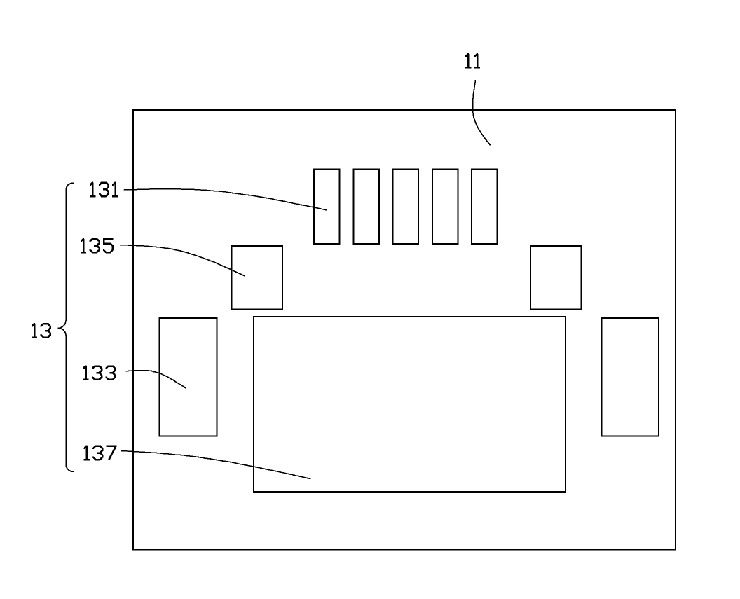

### BACKGROUND

1. Technical Field

The present disclosure relates to a slide rail structure.

2. Description of Related Art

A circuit board includes pads to connect to electric elements, such as USB connectors. The USB connectors are commonly mounted on the circuit board by soldering pins of the USB connectors and the pads together. The solder areas between the USB connectors and the pads are small, such that the connection force between the USB connectors and the circuit board is low. In the test result, the USB connectors separate from the pads when pulled by a force of about 31 N to about 33 N.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding portions throughout the figures.

The FIGURE is a perspective view of an exemplary embodiment of a circuit board.

### DETAILED DESCRIPTION

The FIGURE is a perspective view of an exemplary embodiment of a circuit board (not marked). The circuit board includes a base board 11 and a pad array 13 mounted on the base board 11. The pad array 13 includes a plurality of spaced first pads 131, two second pads 133, and two third pads 135. The longitudinal axes of the first pads 131, the second pads 133, and the third pads 135 are all parallel to each other.

The first pads 131 electronically and physically connect to pins of an electric element, such as a Mini USB connector. In this exemplary embodiment, the numbers of the first pads 131 are five, which are corresponding to the numbers of pins of a Mini USB connector.

The two second pads 133 and two third pads 135 physically connect to the bottom of the electric element. The two third pads 135 are between the first pads 131 and the second pads 133, and furthermore are symmetrically outside two ends of the group of the first pads 131. The two second pads 133 are symmetrically outside two ends of the group of the third pads 135.

The pad array 13 further includes a fourth pad 137 disposed between the two second pads 133. The fourth pad 137 abuts the third pads 135 and physically connects to the bottom of the electric element. In this exemplary embodiment, the first pads 131, the second pads 133, the third pads 135, and the fourth pad 137 are rectangular.

In assembly, five pins (VCC, D−, D+, ID, and GND) of a Mini USB connector are soldered to the first pads 131. The bottom of the Mini USB connector is soldered to the second pads 133, the third pads 135, and the fourth pad 137. In the test result, the Mini USB connector comes off the circuit board when a pulling force applied to the Mini USB connector is approximately 50 N.

In another exemplary embodiment, the numbers of the first pads 131 can be four, which is corresponding to four pins (VCC, D−, D+, and GND) of a USB connector.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of portions within the principles of the present invention to the full extent indicated by the broad general meaning of the terms in which the appended claims are expressed.

What is claimed is:

1. A circuit board, comprising a base board and a pad array, the pad array comprising:
a plurality of spaced first pads configured to electronically and physically connect to an electric element; and
two second pads and two third pads configured to physically connect to the electric element;
wherein the longitudinal axes of the first pads, the second pads, and the third pads are all parallel to each other.

2. The circuit board of claim 1, wherein
the two third pads are symmetrically outside two ends of the group of the first pads; and
the two second pads are symmetrically outside two ends of the group of the third pads.

3. The circuit board of claim 2, wherein the third pads are between the first pads and the second pads.

4. The circuit board of claim 3, further comprises a fourth pad between the two second pads.

5. The circuit board of claim 4, wherein the fourth pad abuts the two third pads.

6. The circuit board of claim 4, wherein the fourth pad is rectangular.

7. The circuit board of claim 2, wherein the first pads, the second pads, and the third pads are rectangular.
